(19) United States
(12) Patent Application Publication
(10) Pub. No.: US 2024/0080618 A1
(43) Pub. Date: Mar. 7, 2024

(54) OUT-OF-HEAD LOCALIZATION PROCESSING DEVICE, OUT-OF-HEAD LOCALIZATION PROCESSING METHOD, AND COMPUTER-READABLE MEDIUM

(71) Applicant: JVCKENWOOD Corporation, Yokohama-shi (JP)

(72) Inventor: Takahiro GEJO, Yokohama-shi (JP)

(21) Appl. No.: 18/242,396

(22) Filed: Sep. 5, 2023

(30) Foreign Application Priority Data
Sep. 6, 2022 (JP) 2022-141455

(51) Int. Cl. H04R 3/04; H04R 5/033; H04R 5/04

(52) U.S. Cl. CPC H04R 3/04; H04R 5/033; H04R 5/04

(57) ABSTRACT

An out-of-head localization processing device according to this embodiment includes: a frequency analysis unit configured to perform frequency analysis on an input signal; an inverse filter unit configured to convolve an inverse filter to the input signal and to generate an output signal; a microphone configured to pick up the output signal output from an output unit; an adaptive control unit configured to: calculate an error function based on the input signal and a sound pickup signal; perform adaptive control so that the error function is minimized; and change an adaptation speed according to a result of the frequency analysis, the input signal being a signal to which a predetermined filter coefficient is convolved; and a correction unit configured to correct the inverse filter according to a result of the adaptive control.

### CROSS REFERENCE TO RELATED APPLICATION

This application is based upon and claims the benefit of priority from Japanese patent application No. 2022-141455, filed on Sep. 6, 2022, the disclosure of which is incorporated herein in its entirety by reference.

### BACKGROUND

The present disclosure relates to an out-of-head localization processing device, an out-of-head localization processing method, and a computer-readable medium.

Sound localization techniques include an out-of-head localization technique, which localizes sound images outside the head of a listener by using headphones. The out-of-head localization technique works to cancels characteristics from headphones to the ears (headphone characteristics), and gives two characteristics from one speaker (monaural speaker) to the ears (spatial acoustic transfer characteristics). This localizes the sound images outside the head.

In out-of-head localization reproduction with a stereo speaker, measurement signals (impulse sounds etc.) that are output from 2-channel (which is referred to hereinafter as “ch”) speakers are recorded by microphones (which can be also called “mike”) placed on the listener's ears. Then, the processing device generates a filter based on sound pickup signals obtained by picking up the measurement signal. The generated filter is convolved to 2ch audio signals, thereby implementing out-of-head localization reproduction.

In addition, to generate a filter to cancel headphone-to-ear characteristics, which is called an inverse filter, characteristics from the headphones to a vicinity of the ear or the eardrum (also referred to as ear canal transfer function ECTF, or ear canal transfer characteristics) are measured with a microphone placed in the listener's ear.

Japanese Unexamined Patent Application Publication No. 2022-20259 discloses a device for measuring ear canal transfer characteristics using headphones and a microphones. Then, an inverse filter is generated based on a sound pickup signal picked up by the microphones.

In such an out-of-head localization processing device, it is desirable to use a more appropriate filter to perform out-of-head localization processing.

### SUMMARY

An out-of-head localization processing device according to this embodiment includes: an input signal generation unit configured to add convolution signals and thereby generate an input signal, the convolution signals being obtained by respectively convolving spatial acoustic filters to a plurality of reproduced signals; a frequency analysis unit configured to perform frequency analysis on the input signal; an inverse filter unit configured to convolve an inverse filter to the input signal and to generate an output signal; an output unit configured to output the output signal to an ear of a user, the output unit being a headphone or an earphone; a microphone, to be worn on the ear of the user, configured to pick up the output signal output from the output unit and thereby acquire a sound pickup signal; an adaptive control unit configured to: calculate an error function based on the input signal and the sound pickup signal; perform adaptive control so that the error function is minimized; and change an adaptation speed according to a result of the frequency analysis, the input signal being a signal to which a predetermined filter coefficient has been convolved; and a correction unit configured to correct the inverse filter according to a result of the adaptive control.

An out-of-head localization processing method according to this embodiment includes: a step of adding a plurality of reproduced signals and thereby generating an input signal, the plurality of reproduced signals being signals to which spatial acoustic filters have been respectively convolved; a step of performing frequency analysis on the input signal; a step of convolving an inverse filter to the input signal and generating an output signal; a step of outputting the output signal to an ear of a user through an output unit that is a headphone or an earphone; a step of picking up the output signal output from the output unit and thereby acquiring a sound pickup signal, using a microphone worn on the ear of the user; a step of: calculating an error function based on the input signal and the sound pickup signal; and performing adaptive control so that the error function is minimized, the input signal being a signal to which a predetermined filter coefficient has been convolved; a step of changing adaptation speed of the adaptive control according to a result of the frequency analysis; and a step of correcting the inverse filter based on a result of the adaptive control.

A computer-readable medium according to this embodiment is a non-transitory computer-readable medium storing a program configured to cause a computer to execute an out-of-head localization processing method, the out-of-head localization processing method including: a step of adding a plurality of reproduced signals and thereby generating an input signal, the plurality of reproduced signals being signals to which spatial acoustic filters have been respectively convolved; a step of performing frequency analysis on the input signal; a step of convolving an inverse filter to the input signal and generating an output signal; a step of outputting the output signal to an ear of a user through an output unit that is a headphone or an earphone; a step of picking up the output signal output from the output unit and thereby acquiring a sound pickup signal, using a microphone worn on the ear of the user; a step of: calculating an error function based on the input signal and the sound pickup signal; and performing adaptive control so that the error function is minimized, the input signal being a signal to which a predetermined filter coefficient has been convolved; a step of changing adaptation speed of the adaptive control according to a result of the frequency analysis; and a step of correcting the inverse filter based on a result of the adaptive control.

An object of the present disclosure can be to provide an out-of-head localization processing device, an out-of-head localization processing method, and a computer-readable medium that can perform out-of-head localization processing using a more appropriate filter.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing an out-of-head localization processing device according to this embodiment;

FIG. 2 is a control block diagram showing a configuration for performing adaptive control on an inverse filter;

FIG. 3 is a flowchart showing an out-of-head localization processing method according to this embodiment;

FIG. 4 is a flowchart showing processing for correcting an inverse filter through adaptive control; and

FIG. 5 is a graph showing an inverse filter before and after correction.

### DETAILED DESCRIPTION

The overview of a sound localization processing according to this embodiment is described hereinafter. An out-of-head localization processing according to this embodiment performs out-of-head localization processing by using spatial acoustic transfer characteristics and ear canal transfer characteristics. The spatial acoustic transfer characteristics are transfer characteristics from a sound source such as speakers to the ear canal. The ear canal transfer characteristics is a transfer characteristics from the speaker unit of headphones or earphones to the eardrum. In this embodiment, the spatial acoustic transfer characteristics are measured with no headphones or no earphones worn, the ear canal transfer characteristics (also referred to as headphone characteristics or earphone characteristics) are measured with headphones or earphones worn, and out-of-head localization processing is implemented with these measurement data. One of the technical features of this embodiment relates to an acoustic system for measuring ear canal transfer characteristics and generating an inverse filter.

The out-of-head localization processing according to this embodiment is executed on a user terminal such as a personal computer, a smart phone, or a tablet PC. The user terminal is an information processing device including processing means such as a processor, storage means such as a memory or a hard disk, display means such as a liquid crystal monitor, and input means such as a touch panel, a button, a keyboard and a mouse. The user terminal may have a communication function for transmitting and receiving data. Further, the user terminal is connected to output means (an output unit) with headphones or earphones. The connection between the user terminal and the output means may be a wired connection or a wireless connection.

### First Embodiment

### (Out-of-Head Localization Processing Device)

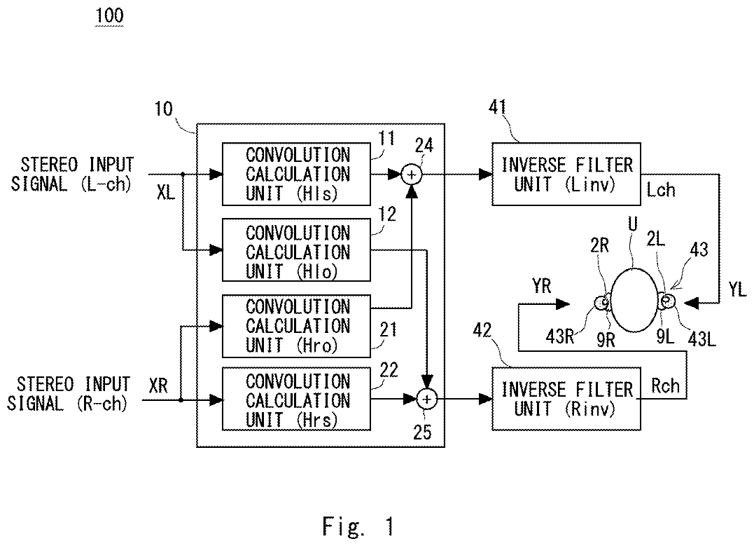

FIG. 1 shows a block diagram of an out-of-head localization processing device 100, which is an example of a sound field reproducing device according to this embodiment. The out-of-head localization processing device 100 reproduces a sound field for the user U who wears the earphones 43. Thus, the out-of-head localization processing device 100 performs sound localization processing for L-ch and R-ch stereo signals XL and XR. The L-ch and R-ch stereo signals XL and XR are analog audio reproduced signals that are output from a CD (Compact Disc) player or the like or digital audio data such as mp3 (MPEG Audio Layer-3). Note that the audio reproduced signals or digital audio data are collectively referred to as a reproduced signal. In other words, the L-ch and R-ch stereo signals XL and XR are reproduced signals.

In this embodiment, the out-of-head localization processing device 100 performs arithmetic processing for appropriately generating filters. An arithmetic processing unit of the out-of-head localization processing device 100 is a personal computer (PC), a tablet terminal, a smart phone, or the like, and includes a memory and a processor. The memory stores processing programs, various parameters, measurement data, and the like. The processor executes a processing program stored in the memory. The processor executes the processing program and thereby each process is executed. The processor may be, for example, a CPU (Central Processing Unit), an FPGA (Field-Programmable Gate Array), a DSP (Digital Signal Processor), an ASIC (Application Specific Integrated Circuit), a GPU (Graphics Processing Unit), or the like.

Note that the out-of-head localization processing device 100 is not limited to a physically single device, and a part of processing may be performed in a different device. For example, a part of processing may be performed by a smart phone or the like, and the remaining processing may be performed by a DSP (Digital Signal Processor) built in the earphones 43 or the like.

The out-of-head localization processing device 100 includes an out-of-head localization unit 10, an inverse filter unit 41 for storing an inverse filter Linv, an inverse filter unit 42 for storing an inverse filter Rinv, and earphones 43. The out-of-head localization unit 10, the inverse filter unit 41, and the inverse filter unit 42 can be specifically implemented by a processor or the like. Further, the out-of-head localization processing device 100 includes left and right microphones 2L and 2R.

The out-of-head localization unit 10 includes convolution calculation units 11 to 12 and 21 to 22 for storing the spatial acoustic transfer characteristics Hls, Hlo, Hro, and Hrs, and adders 24, 25. The convolution calculation units 11 to 12 and 21 to 22 perform convolution processing using the spatial acoustic transfer characteristics. The stereo signals XL and XR from a CD player or the like are input to the out-of-head localization unit 10. The spatial acoustic transfer characteristics are set to the out-of-head localization unit 10. The out-of-head localization unit 10 convolves a filter of the spatial acoustic transfer characteristics (which is hereinafter referred to also as a spatial acoustic filter) into each of the stereo signals XL and XR. The spatial acoustic transfer characteristics may be a head-related transfer function HRTF measured in the head or auricle of a person being measured, or may be the head-related transfer function of a dummy head or a third person.

The spatial acoustic transfer function is a set of four spatial acoustic transfer characteristics Hls, Hlo, Hro and Hrs. Data used for convolution in the convolution calculation units 11 to 12 and 21 to 22 is a spatial acoustic filter. The spatial acoustic filter is generated by cutting out the spatial acoustic transfer characteristics Hls, Hlo, Hro and Hrs with a predetermined filter length.

Each of the spatial acoustic transfer characteristics Hls, Hlo, Hro and Hrs may be acquired in advance by impulse response measurement or the like. For example, the user U wears microphones on the left and right ears 9L and 9R, respectively. Left and right speakers placed in front of the user U output impulse sounds for performing impulse response measurements. Then, the measurement signals such as the impulse sounds output from the speakers are picked up by the microphones. The spatial acoustic transfer characteristics Hls, Hlo, Hro and Hrs are acquired based on sound pickup signals in the microphones. The spatial acoustic transfer characteristics Hls between the left speaker and the left microphone, the spatial acoustic transfer characteristics Hlo between the left speaker and the right microphone, the spatial acoustic transfer characteristics Hro between the right speaker and the left microphone, and the spatial acoustic transfer characteristics Hrs between the right speaker and the right microphone are measured.

The convolution calculation unit 11 convolves the spatial acoustic filter in accordance with the spatial acoustic transfer characteristics Hls to the L-ch stereo signal XL. The convolution calculation unit 11 outputs convolution calculation data to the adder 24. The convolution calculation unit 21 convolves the spatial acoustic filter in accordance with the spatial acoustic transfer characteristics Hro to the R-ch stereo signal XR. The convolution calculation unit 21 outputs convolution calculation data to the adder 24. The adder 24 adds the two pieces of convolution calculation data and outputs the resultant data to the inverse filter unit 41.

The convolution calculation unit 12 convolves the spatial acoustic filter in accordance with the spatial acoustic transfer characteristics Hlo to the L-ch stereo signal XL. The convolution calculation unit 12 outputs the convolution calculation data to the adder 25. The convolution calculation unit 22 convolves the spatial acoustic filter in accordance with the spatial acoustic transfer characteristics Hrs to the R-ch stereo signal XR. The convolution calculation unit 22 outputs convolution calculation data to the adder 25. The adder 25 adds the two pieces of convolution calculation data and outputs the resultant data to the inverse filter unit 42.

Inverse filters Linv and Rinv that cancel earphone characteristics (characteristics between the driver units of the earphones 43 and the microphones) are set in the inverse filter units 41 and 42. Then, the inverse filters Linv and Rinv are convolved into the reproduced signals (input signals) subjected to processing in the out-of-head localization unit 10. The inverse filter unit 41 convolves the inverse filter Linv of the L-ch earphone characteristics (the ear canal transfer characteristics) to the L-ch signal from the adder 24. Likewise, the filter unit 42 convolves the inverse filter Rinv of the R-ch earphone characteristics (ear canal transfer characteristics) to the R-ch signal from the adder 25. The inverse filters Linv and Rinv cancel out the characteristics from the driver units to the microphones or eardrums when the earphones 43 are worn. The microphones 2L and 2R are mounted on the earphones 43, as will be described later. For example, feedback microphones for noise cancellation can be used to measure the ear canal transfer characteristics.

The inverse filter unit 41 outputs the processed L-ch signal YL to the left unit 43L of the earphones 43. The inverse filter unit 42 outputs the processed R-ch signal YR to the right unit 43R of the earphones 43. The user U wears the earphones 43. The earphones 43 output the L-ch signal YL and the R-ch signal YR (hereinafter, the L-ch signal YL and the R-ch signal YR are collectively referred to as a stereo signal) toward the user U. This can reproduce sound images localized outside the head of the user U.

As described above, the out-of-head localization processing device 100 performs out-of-head localization processing using the spatial acoustic filters in accordance with the spatial acoustic transfer characteristics Hls, Hlo, Hro, and Hrs, and the inverse filters Linv and Rinv of the earphone characteristics (ear canal transfer characteristics). In the following description, the spatial acoustic filters in accordance with the spatial acoustic transfer characteristics Hls, Hlo, Hro, and Hrs, and the inverse filters Linv and Rinv of the earphone characteristics are collectively referred to as an out-of-head localization processing filter. In the case of 2ch stereo reproduced signals, the out-of-head localization filter is composed of four spatial acoustic filters and two inverse filters. The out-of-head localization processing device 100 then carries out convolution calculation processing on the stereo reproduced signals by using the out-of-head localization filter composed of totally six filters and thereby performs out-of-head localization processing. The out-of-head localization filter is preferably based on the measurement of the individual user U. For example, the out-of-head localization filter is set based on sound pickup signals picked up by the microphones worn on the ears of the user U.

In this way, the spatial acoustic filters and the inverse filters Linv and Rinv for ear canal transfer characteristics are filters for audio signals. These filters are convolved into the reproduced signals (stereo signals XL and XR), and thereby the out-of-head localization processing device 100 executes the out-of-head localization processing.

In this embodiment, one of the technical features is processing of generating the inverse filters of the ear canal transfer characteristics. More specifically, the out-of-head localization processing device 100 generates inverse filters through adaptive control. Hereinafter, the generation of the inverse filter through adaptive control will be described. A user U wears microphones 2L and 2R on the left and right ears 9L and 9R. For example, the microphone 2L is attached to the left unit 43L and the microphone 2R is attached to the right unit 43R. When the user U wears the earphones 43, the microphones 2L and 2R are attached to the ears 9L and 9R. The microphones 2L and 2R may be placed anywhere between the entrance of the ear canal and the eardrum.

The microphone 2L picks up the output signal output from the left unit 43L. The microphone 2R picks up the output signal output from the right unit 43R. Then, adaptive control is applied to the inverse filters Linv and Rinv based on the left and right sound pickup signals. Thus, out-of-head localization processing using an appropriate inverse filter can be performed.

The ear canal transfer characteristics change according to the shapes of the ear canals and the areas around the auricles. For example, the ear canals and the areas around the auricles constantly change due to the movement of various muscles around the head. It is also known that the shapes of the ear canals and their outlets change minutely due to swelling and physical condition. It is difficult that current earpiece sizes perfectly fit every user. Even in listening, it is difficult that degree of fit depending on wearing states is maintained to be constant. Therefore, when there is such a change, the out-of-head localization processing device 100 can perform adaptive control to use appropriate inverse filters.

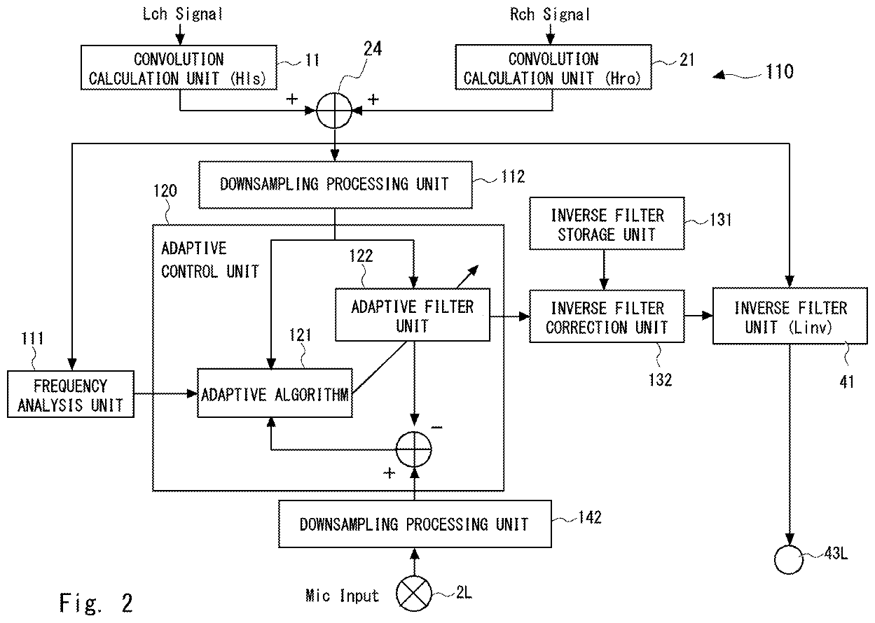

Hereinafter, adaptive control of the inverse filter will be described with reference to FIG. 2. FIG. 2 is a control block showing a configuration of a processing device that performs an adaptive control on an inverse filter. Note that FIG. 2 is a diagram for describing the processing related to the left inverse filter (Linv). Since the processing related to the right inverse filter is similar to the processing related to the left inverse filter, the description thereof will be omitted as appropriate.

The out-of-head localization processing device 100 includes an input signal generation unit 110, a frequency analysis unit 111, a downsampling processing unit 112, an adaptive control unit 120, an inverse filter storage unit 131, an inverse filter correction unit 132, an inverse filter unit 41, and a downsampling processing unit 142.

The input signal generation unit 110 generates an input signal to be input to the adaptive control unit 120. The input signal generation unit 110 corresponds to the out-of-head localization unit 10 in FIG. 1. The input signal generation unit 110 includes a convolution calculation unit 11, a convolution calculation unit 21, and an adder 24. The input signal generation unit 110 corresponds to the out-of-head localization unit 10 in FIG. 1.

The convolution calculation unit 11, the convolution calculation unit 21, and the adder 24 are similar to those described in FIG. 1. In other words, the convolution calculation unit 11 convolves a spatial acoustic filter corresponding to the spatial acoustic transfer characteristics hls to the L-ch stereo signal XL, and thereby generates a first convolution signal. The convolution calculation unit 21 convolves the spatial acoustic filter indicating the spatial acoustic transfer characteristics Hro to the R-ch stereo signal XR. Signals output from the convolution calculation unit 11 and the convolution calculation unit 21 are referred to as a first convolution signal and a second convolution signal, respectively.

The adder 24 adds the first convolution signal and the second convolution signal to generate an addition signal. The input signal generation unit 110 generates the addition signal as an input signal. The input signal generation unit 110 outputs the input signal to the frequency analysis unit 111, the downsampling processing unit 112, and the inverse filter unit 41.

The frequency analysis unit 111 performs frequency analysis on the input signal. The frequency analysis unit 111 controls adaptation speed of the adaptive control unit 120 according to the result of the frequency analysis. For example, the frequency analysis unit 111 monitors a signal level in a low frequency range of the input signal. The frequency analysis unit 111 calculates the amplitude spectrum and the like of the input signal by FFT or the like. Then, frequency analysis unit 111 calculates the signal level in the low frequency range of the amplitude spectrum. The low frequency range is, for example, the band from 10 Hz (minimum frequency) to 300 Hz. Then, the average value of the amplitude values in the low frequency range can be used as the signal level in the low frequency range. Of course, the frequency range for determining the signal level is not limited to the above low frequency range.

The frequency analysis unit 111 controls adaptation speed of the adaptive control unit 120 according to the signal level in the low frequency range. Specifically, when the signal level in the low frequency range is high, the frequency analysis unit 111 increases the adaptation speed of the adaptive control unit 120. When the signal level in the low frequency range is low, the frequency analysis unit 111 slows down the adaptation speed of the adaptive control unit 120. Thus, the frequency analysis unit 111 adjusts the adaptation speed according to the signal level. For example, the frequency analysis unit 111 may adjust the adaptation speed step by step or continuously according to the signal level. For example, the signal level in the low frequency range can be, for example, the total value or average value of the amplitude values of the amplitude spectrum.

The downsampling processing unit 112 downsamples the input signal. The downsampling processing unit 112 lowers the sampling frequency to such an extent that the upper limit frequency of the low frequency range to be adapted by this processing does not fall below the Nyquist frequency. The downsampling processing unit 112 causes the input signal to pass through a decimation filter whose cutoff frequency is the Nyquist frequency after AD conversion and then performs thinning processing. The downsampling processing unit 112 outputs the downsampled input signal to the adaptive control unit 120.

Note that the downsampling processing unit 112 can be omitted. In other words, an input signal that is not downsampled may be input to the adaptive control unit 120.

The inverse filter storage unit 131 stores inverse filters set in advance. The inverse filter stored in the inverse filter storage unit 131 becomes initially set inverse filter. The initially set inverse filter may be obtained based on personal measurement of the user U, or may be obtained by measurement of another user or the like. For example, the user U may select an appropriate inverse filter from among a plurality of inverse filters stored in a server or the like.

In personal measurement, the user U wears the earphones 43. The earphones 43 respectively output measurement signals such as impulse sounds. For example, the measurement signals are impulse signals, TSP (Time Stretched Pulse) signals, frequency sweep signals, M-sequence (Maximum Length Sequence) signals, or the like. The microphones 2L and 2R built in the earphones 43 perform impulse response measurement. Thus, the spatial transfer characteristics (ear canal transfer characteristics ECTF) from the driver units of the earphones 43 to the microphones 2L and 2R are measured. Then, an inverse filter for canceling the ear canal transfer characteristics is calculated. The inverse filter storage unit 131 stores the inverse filter calculated in this way as an initial setting.

The inverse filter correction unit 132 extracts and corrects the inverse filter stored in the inverse filter storage unit 131 according to the control result of the adaptive control, which will be described later. The inverse filter correction unit 132 outputs the corrected inverse filter to the inverse filter unit 41. The inverse filter unit 41 convolves the corrected inverse filter to the input signal and outputs the resultant signal to the left unit 43L of the earphones 43. The input signal to which the inverse filter is convolved becomes the output signal to be output from the left unit 43L. In the initial state, the inverse filter unit 41 convolves the inverse filter stored in the inverse filter storage unit 131 the input signal. The inverse filter is updated as needed according to the result of adaptive control.

The microphone 2L picks up the output signal output from the left unit 43L and outputs the sound pickup signal to the downsampling processing unit 142. The downsampling processing unit 142 downsamples the sound pickup signal. The processing of the downsampling processing unit 142 is similar to that of the downsampling processing unit 112. The downsampling processing unit 142 outputs the downsampled sound pickup signal to the adaptive control unit 120. Accordingly, the adaptive control unit 120 performs processing based on the sound pickup signal and the input signal downsampled with the same sampling frequency.

The downsampling processing unit 142 can be omitted, like the downsampling processing unit 112. In other words, a sound pickup signal that is not downsampled may be input to the adaptive control unit 120. In other words, the sampling frequency of the sound pickup signal just needs to be the same as the input signal.

The adaptive control unit 120 performs adaptive processing based on the sound pickup signal and the input signal. For example, an adaptive filter unit 122 holds a filter having a predetermined filter coefficient. The adaptive filter unit 122 filters the input signal using a filter held therein. Specifically, the adaptive filter unit 122 convolves the filter coefficient of the filter to the input signal. The input signal filtered by the adaptive filter unit 122 is referred to as a filter signal.

The adaptive control unit 120 generates an error signal based on the sound pickup signal and the filter signal. For example, the adaptive control unit 120 generates the error signal by subtracting the filter signal from the sound pickup signal. The adaptive control unit 120 has an adaptive algorithm 121 that controls the filter coefficient of the adaptive filter unit 122 so that the error signal is minimized. The adaptive algorithm 121 is an optimization algorithm that minimizes the error function. Algorithms to be used for minimizing the error function can be algorithms such as LMS (Least Mean Square) and NMLS (Normalized Least Mean Square). According to a predetermined algorithm, the adaptive algorithm changes the filter coefficient so that the error function converges. Furthermore, the adaptive control unit 120 changes the adaptation speed of the adaptive algorithm 121 based on the frequency analysis result of the frequency analysis unit 111.

The inverse filter correction unit 132 reads the inverse filter from the inverse filter storage unit 131. The inverse filter correction unit 132 performs frequency analysis on the filter coefficient of the adaptive filter, and corrects the read inverse filter according to the analysis result. For example, the inverse filter correction unit 132 corrects the amplitude value of the amplitude spectrum or the power value of the power spectrum of the inverse filter. The inverse filter correction unit 132 transmits the corrected inverse filter to the inverse filter unit 41. As a result, the filter coefficients of the inverse filter are updated in the inverse filter unit 41.

The inverse filter unit 41 convolves the inverse filter corrected by adaptive control to the input signal, and thereby generates output signal. The left unit 43L outputs the output signal toward the ear of the user U. Thus, the user U can listen to the output signal that have undergone appropriate out-of-head localization processing. When the ear canal transfer characteristics change, the out-of-head localization processing device 100 can perform out-of-head localization processing using an appropriate inverse filter.

Note that, the inverse filter correction unit 132 may correct the inverse filter only when a difference, between the correction amount in the last update of the filter coefficient and the correction amount in the current update of the filter coefficient, is equal to or greater than a predetermined value. In other words, the inverse filter correction unit 132 compares the last correction amount and the current correction amount. When the difference between the correction amounts is less than a predetermined value, the inverse filter correction unit 132 does not correct the inverse filter. In this case, the inverse filter correction unit 132 does not transmit the corrected inverse filter to the inverse filter unit 41. Therefore, the inverse filter unit 41 convolves the inverse filter before correction. In other words, the inverse filter unit 41 uses the last updated inverse filter until the difference between the correction amounts reaches or exceeds a constant value.

When the difference between the correction amounts is equal to or greater than the constant value, the inverse filter correction unit 132 transmits the corrected inverse filter to the inverse filter unit 41. Thereby, the inverse filter of the inverse filter unit 41 is updated. Then, the inverse filter unit 41 convolves the updated inverse filter to the input signal.

Note that the inverse filter Rinv on the right can also undergo adaptive control through similar processing. Specifically, the input signal generation unit 110 uses filters that indicate spatial acoustic transfer characteristics Hlo and Hrs as spatial acoustic filters to be convolved to the left and right reproduced signals. Then, the inverse filter unit 42 convolves the right inverse filter Rinv to the input signal. The microphone 2R picks up the output signal to which the right inverse filter Rinv is convolved. Since other processing is similar to those described above, the description thereof is omitted.

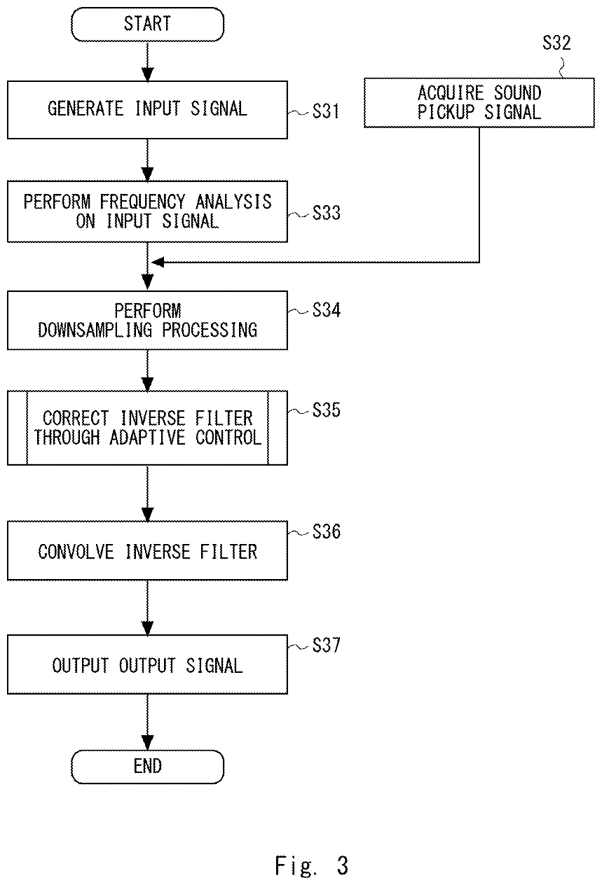

Next, an out-of-head localization processing method will be described with reference to FIG. 3. FIG. 3 is a flowchart showing an out-of-head localization processing method.

First, the input signal generation unit 110 generates an input signal from the left and right reproduced signals (S31). In other words, the convolution calculation unit 11 convolves the spatial acoustic filter to the left reproduced signal. The convolution calculation unit 21 convolves the spatial acoustic filter to the right reproduced signal. The adder 24 adds the left and right reproduced signals to which the spatial acoustic filters have been convolved. The addition signal output from the adder 24 becomes an input signal.

In parallel with step S31, the microphones 2L and 2R acquire sound pickup signals (S32). In other words, the left unit 43L and the right unit 43R serve as output units that output the output signals to which the inverse filters have been convolved toward the ears 9L and 9R of the user U. The left microphone 2L and right microphone 2R respectively pick up the output signals from the left unit 43L and the right unit 43R, so that sound pickup signals are acquired.

The frequency analysis unit 111 performs frequency analysis of the input signal. In other words, the frequency analysis unit 111 calculates the amplitude spectrum by FFT or the like, and calculates an amplitude level in a low frequency range.

The downsampling processing unit 112 and the downsampling processing unit 142 respectively perform downsampling processing on the input signal and the sound pickup signal (S34), thereby generating the downsampled input signal and the sound pickup signal. Note that this processing can be omitted.

Next, the adaptive control unit 120 performs adaptive control based on the input signal and the sound pickup signal, so that the inverse filter correction unit 132 corrects the inverse filter (S35). This processing will be described later.

The inverse filter units 41 and 42 convolve the inverse filters to the input signals (S36). This generates output signals. Then, the left unit 43L and the right unit 43R of the earphones 43 output the output signals toward the left and right ears 9L and 9R (S37). Thus, the user U can listen to the reproduced signals subjected to the out-of-head localization processing.

The out-of-head localization processing device 100 repeats the flow shown in FIG. 3. Thus, the inverse filter can be generated by adaptive control. Therefore, even if the ear canal transfer characteristics change with time, the out-of-head localization processing device 100 can use an appropriate inverse filter. Even if the shapes of the ear canals or the areas around the auricles change according to the motion or the state of the user, appropriate inverse filter is generated by adaptive control. Also, even if the wearing state of the earphones 43 with respect to the ears changes, an appropriate inverse filter is generated by adaptive control.

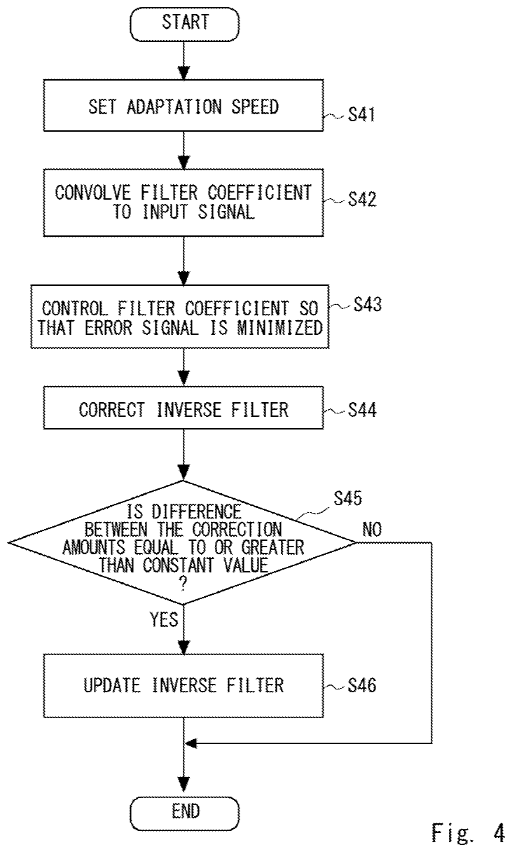

Next, processing of step S35 will be described with FIG. 4. FIG. 4 is a flowchart for describing the details of the processing in step S35.

First, the adaptive control unit 120 sets the adaptation speed of the adaptive algorithm 121 according to the frequency analysis result of the input signal (S41). For example, when the signal level in the low frequency range of the input signal is high, the adaptive control unit 120 increases the adaptation speed, and when the signal level in the low frequency range of the input signal is low, the adaptive control unit 120 decreases the adaptation speed. The adaptive control unit 120 can control the adaptation speed by a step size parameter of the adaptive algorithm 121 or the like. The adaptive control unit 120 changes the step size parameter to change the amount of update, and therefore can control the adaptation speed.

Next, the adaptive filter unit 122 convolves the filter coefficient to the input signal (S42). This generates the filter signals. The adaptive algorithm 121 controls the filter coefficient of the adaptive filter unit 122 so that the adaptive algorithm 121 minimizes the error signal (S43). For example, the adaptive algorithm 121 generates an error signal by subtracting the filter signal from the sound pickup signal. The adaptive algorithm 121 uses an optimization algorithm such as LMS to adjust the filter coefficient to minimize the error signal. In other words, the adaptive algorithm 121 continuously updates the filter coefficient of the adaptive filter unit 122 so that the error signal converges.

As described above, the adaptation algorithm 121 changes the adaptation speed according to the analysis result of the frequency analysis unit 111. For example, the adaptive algorithm 121 changes the step size parameter according to the signal level in the low frequency range. Thereby, adaptation to unnecessary signal and erroneous adaptation can be prevented. For example, adaptation to sudden noise or the like can be prevented.

The inverse filter correction unit 132 corrects the inverse filter (S44). In an initial state, the inverse filter correction unit 132 reads an initially set inverse filter stored in the inverse filter storage unit 131. Also, the inverse filter correction unit 132 performs frequency analysis on the filter coefficient of the adaptive filter unit 122. The inverse filter correction unit 132 corrects the filter coefficient of the initially set inverse filter based on the frequency analysis result of the filter coefficient. For example, the inverse filter correction unit 132 corrects the inverse filter in terms of frequency. The inverse filter correction unit 132 changes amplitude values such as the amplitude spectrum of the inverse filter. After updating the inverse filter by adaptive control, the inverse filter correction unit 132 corrects the filter coefficient of the inverse filter updated last time.

The inverse filter correction unit 132 determines whether the difference between the last correction amount of the inverse filter and the current correction amount thereof is equal to or greater than the constant value (S45). For example, the inverse filter correction unit 132 stores the correction amount of the filter coefficient of the inverse filter when updating the filter coefficient. The correction amount can be obtained by summing the correction amounts of the individual filter coefficients. The inverse filter correction unit 132 obtains the difference between the correction amounts by subtracting the last correction amount from the current correction amount. Then, the inverse filter correction unit 132 compares the difference between the correction amounts with a constant value (threshold value) set in advance.

When the difference between the correction amounts is equal to or greater than the constant value (YES in S45), the inverse filter correction unit 132 updates the filter coefficient of the inverse filter unit 41 (S46). Therefore, an inverse filter with updated filter coefficient is convolved to the input signal. In other words, the inverse filter after correction is convolved to the input signal.

When the difference between the correction amounts is less than the constant value (NO in S45), the processing ends without updating the filter coefficient. Therefore, the inverse filter with the filter coefficient with no update of the filter coefficient is convolved to the input signal. In other words, the inverse filter before correction is convolved to the input signal.

The inverse filter correction unit 132 updates the inverse filter of the inverse filter unit 41 when the difference between the correction amounts of the inverse filter becomes large. This updates the filter coefficient of the inverse filter. The inverse filter unit 41 convolves the inverse filter after update to the input signal. In this way, the inverse filter correction unit 132 updates the inverse filter of the inverse filter unit 41 when there is a large change in the ear canal transfer characteristics. The out-of-head localization processing device 100 can perform out-of-head localization processing using the corrected inverse filter.

The inverse filter correction unit 132 determines whether to update the filter coefficient of the inverse filter according to the difference between the correction amounts. For example, when the wearing state of the earphones 43 changes, the ear canal transfer characteristics changes greatly. This significantly changes the filter coefficient of adaptive filter unit 122. In such a case, the inverse filter correction unit 132 transmits the inverse filter after correction to the inverse filter unit 41. Thereby, the inverse filter of the inverse filter unit 41 is updated. The inverse filter unit 41 convolves the inverse filter after correction to the input signal. Contrarily, when the difference between the correction amounts is small, the inverse filter correction unit 132 does not update the filter of the inverse filter unit 41. In this way, when the change in the ear canal transfer characteristics is small, the processing of updating the inverse filter is unnecessary. Therefore, the processing load can be reduced.

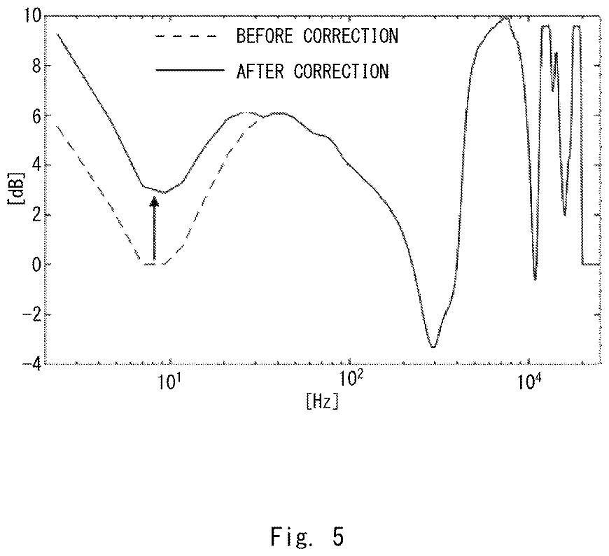

FIG. 5 is a graph showing the power spectrum of the inverse filter before and after correction. In FIG. 5, the power spectrum of the inverse filter before correction is indicated by a dashed line, and the power spectrum of the inverse filter after correction is indicated by a solid line. Only the low frequency range below 300 Hz is corrected here. Of course, the band for correcting the inverse filter is not limited to 300 Hz or less. The inverse filter correction unit 132 may correct the entire band, or may correct only a part of the band.

In this embodiment, the adaptive control unit 120 processes the signal subjected to downsampling processing. In this way, the amount of processing can be significantly reduced. Therefore, even a reproduced signals of a high-resolution sound source can be appropriately processed without delay. Furthermore, the out-of-head localization processing device 100 can be implemented with a DSP device having a low processing speed or the like.

Note that, in the above description, the reproduced signals are 2ch stereo signals of the left and right, but the reproduced signals are not limited to stereo signals. The reproduced signals may be reproduced signals of a multi-channel such as 5ch or 7ch. In this case, spatial acoustic filters corresponding to the number of channels of the multi-channel are set in the input signal generation unit 110. Then, the input signal generation unit 110 convolves the spatial acoustic filter to each of the multi-channel reproduced signals. The input signal generation unit 110 generates an input signal by adding a plurality of convolution signals.

A (The) program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

The above embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. An out-of-head localization processing device comprising:
an input signal generation unit configured to add convolution signals and thereby generate an input signal, the convolution signals being obtained by respectively convolving spatial acoustic filters to a plurality of reproduced signals;
a frequency analysis unit configured to perform frequency analysis on the input signal;
an inverse filter unit configured to convolve an inverse filter to the input signal and to generate an output signal;
an output unit configured to output the output signal to an ear of a user, the output unit being a headphone or an earphone;
a microphone, to be worn on the ear of the user, configured to pick up the output signal output from the output unit and thereby acquire a sound pickup signal;
an adaptive control unit configured to: calculate an error function based on the input signal and the sound pickup signal; perform adaptive control so that the error function is minimized; and change an adaptation speed according to a result of the frequency analysis, the input signal being a signal to which a predetermined filter coefficient has been convolved; and
a correction unit configured to correct the inverse filter according to a result of the adaptive control.

2. The out-of-head localization processing device according to claim 1, wherein
the adaptation speed is increased when the input signal has a high signal level in a predetermined frequency range, and
the adaptation speed is decreased when the input signal has a low signal level in the predetermined frequency range.

3. The out-of-head localization processing device according to claim 1, wherein
the correction unit:
determines whether a difference between a correction amount in a last update of a filter coefficient of the inverse filter and a correction amount in a current update of the filter coefficient of the inverse filter is equal to or greater than a predetermined value; and
updates the filter coefficient of the inverse filter and transmits the updated filter coefficient to the inverse filter unit when a difference between the correction amounts is equal to or greater than a predetermined value.

4. The out-of-head localization processing device according to claim 1, further comprising:
a first downsampling processing unit configured to downsample the input signal with a downsampling frequency; and
a second downsampling processing unit configured to downsample the sound pickup signal with the downsampling frequency,
wherein the adaptive control unit performs processing based on downsampled sound pickup signal and downsampled input signal.

5. An out-of-head localization processing method comprising:
a step of adding a plurality of reproduced signals and thereby generating an input signal, the plurality of reproduced signals being signals to which spatial acoustic filters have been respectively convolved;
a step of performing frequency analysis on the input signal;
a step of convolving an inverse filter to the input signal and generating an output signal;
a step of outputting the output signal to an ear of a user through an output unit that is a headphone or an earphone;
a step of picking up the output signal output from the output unit and thereby acquiring a sound pickup signal, using a microphone worn on the ear of the user;
a step of: calculating an error function based on the input signal and the sound pickup signal; and performing adaptive control so that the error function is minimized, the input signal being a signal to which a predetermined filter coefficient has been convolved;
a step of changing adaptation speed of the adaptive control according to a result of the frequency analysis; and
a step of correcting the inverse filter based on a result of the adaptive control.

6. A non-transitory computer-readable medium storing a program configured to cause a computer to execute an out-of-head localization processing method,
the out-of-head localization processing method including:
a step of adding a plurality of reproduced signals and thereby generating an input signal, the plurality of reproduced signals being signals to which spatial acoustic filters have been respectively convolved;
a step of performing frequency analysis on the input signal;
a step of convolving an inverse filter to the input signal and generating an output signal;
a step of outputting the output signal to an ear of a user through an output unit that is a headphone or an earphone;
a step of picking up the output signal output from the output unit and thereby acquiring a sound pickup signal, using a microphone worn on the ear of the user;
a step of: calculating an error function based on the input signal and the sound pickup signal; and performing adaptive control so that the error function is minimized, the input signal being a signal to which a predetermined filter coefficient has been convolved;
a step of changing adaptation speed of the adaptive control according to a result of the frequency analysis; and
a step of correcting the inverse filter based on a result of the adaptive control.
